(19) United States
(12) Patent Application Publication
(10) Pub. No.: US 2026/0223607 A1
(43) Pub. Date: Jul. 30, 2026

(54) METHOD FOR MANUFACTURING SEMICONDUCTOR DEVICE, METHOD FOR MANUFACTURING DISPLAY DEVICE AND SEMICONDUCTOR DEVICE

(71) Applicant: Magnolia White Corporation, Minato-ku, Tokyo (JP)

(72) Inventors: Masanobu IKEDA, Tokyo (JP); Masumi NISHIMURA, Tokyo (JP); Satoshi ISHIDA, Tokyo (JP)

(73) Assignee: Magnolia White Corporation, Minato-ku, Tokyo (JP)

(21) Appl. No.: 19/529,256

(22) Filed: Feb. 4, 2026

Related U.S. Application Data
(63) Continuation of application No. PCT/JP2024/021140, filed on Jun. 11, 2024.

(30) Foreign Application Priority Data
Aug. 8, 2023 (JP) 2023-129588

(51) Int. Cl. H10P 14/20; H10H 29/01

(52) U.S. Cl. CPC H10P 14/3808; H10H 29/012; H10P 14/2922; H10P 14/3216; H10P 14/3411; H10P 14/3454

(57) ABSTRACT

A method for manufacturing a semiconductor device includes forming a c-axis oriented aluminum nitride layer on a glass substrate, the c-axis being oriented substantially perpendicular to a surface of the glass substrate, forming an amorphous silicon layer on the c-axis oriented aluminum nitride layer, annealing the amorphous silicon layer to form crystalline polysilicon containing crystal grains whose (111) planes are oriented parallel to the surface of the c-axis oriented aluminum nitride layer, and forming a plurality of transistors including the crystalline polysilicon.

### CROSS-REFERENCE TO RELATED APPLICATIONS

This application is a Continuation of International Patent Application No. PCT/JP2024/021140, filed on Jun. 11, 2024, which claims the benefit of priority to Japanese Patent Application No. 2023-129588, filed on Aug. 8, 2023, the entire contents of which are incorporated herein by reference.

### FIELD

An embodiment of the present invention relates to a method for manufacturing a semiconductor device, a method for manufacturing a display device and the semiconductor device.

### BACKGROUND

In recent years, a display device using a light-emitting element in a display unit has been known as one type of semiconductor device. For example, the light-emitting element is a light-emitting diode (LED), a micro light-emitting diode (micro LED), or an organic electroluminescence (EL) element. Further, for example, the light-emitting element can conduct current when a voltage is applied. As a result, the light-emitting element emits light, and the display device can display images on the display unit.

For example, a transistor is electrically connected to the light-emitting element, and the application of a voltage to the light-emitting element is controlled using the transistor. Patent Literatures 1 to 3 disclose a method for manufacturing a thin film transistor, and Patent Literatures 4 to 6 disclose a display device including a thin film transistor and a light-emitting element.

### SUMMARY

A method for manufacturing a semiconductor device according to an embodiment of the present invention includes forming a c-axis oriented aluminum nitride layer on a glass substrate, the c-axis being oriented substantially perpendicular to a surface of the glass substrate, forming an amorphous silicon layer on the c-axis oriented aluminum nitride layer, annealing the amorphous silicon layer to form crystalline polysilicon containing crystal grains whose (111) planes are oriented parallel to the surface of the c-axis oriented aluminum nitride layer, and forming a plurality of transistors including the crystalline polysilicon.

A method for manufacturing a display device according to an embodiment of the present invention includes forming a c-axis oriented aluminum nitride layer on a glass substrate, the c-axis being oriented substantially perpendicular to a surface of the glass substrate, forming an amorphous silicon layer on the c-axis oriented aluminum nitride layer, annealing the amorphous silicon layer to form crystalline polysilicon containing crystal grains whose (111) planes are oriented parallel to the surface of the c-axis oriented aluminum nitride layer, forming a plurality of transistors including the crystalline polysilicon, forming wiring on the crystalline polysilicon, forming an opening for connecting the c-axis oriented aluminum nitride layer to the wiring, forming, on the glass substrate on which the transistors are formed, a first region including a plurality of pixels, a third region surrounding the first region and including a drive circuit for controlling the plurality of pixels, and a second region surrounding the third region, and the second region is formed to overlap the opening. The second region is formed to overlap the opening. The annealing is performed by excimer laser annealing or solid-state laser annealing. The crystalline polysilicon is formed using laser annealing.

A semiconductor device according to an embodiment of the present invention includes a glass substrate including a first surface, a c-axis oriented aluminum nitride layer arranged on the first surface, the c-axis being oriented substantially perpendicular to the first surface, crystalline polysilicon arranged on the aluminum nitride layer and including crystal grains whose (111) planes are oriented parallel to the surface of the c-axis oriented aluminum nitride layer, a first insulating layer arranged on the crystalline polysilicon, a first electrode arranged on the first insulating layer, a second insulating layer arranged on the first electrode, and a second electrode and a third electrode arranged on the second insulating layer and electrically connected to the crystalline polysilicon.

### BRIEF DESCRIPTION OF DRAWINGS

FIG. 1A is a cross-sectional view showing a configuration of a semiconductor device according to a first embodiment of the present invention.

FIG. 1B is a cross-sectional view showing a configuration of a semiconductor device according to the first embodiment of the present invention.

FIG. 2 is a plan view showing a configuration of the semiconductor device shown in FIG. 1.

FIG. 3 is a sequence diagram showing a method for manufacturing a semiconductor device 10 according to the first embodiment of the present invention.

FIG. 4 is a cross-sectional view showing a method for manufacturing a semiconductor device according to the first embodiment of the present invention.

FIG. 5 is a cross-sectional view showing a method for manufacturing a semiconductor device according to the first embodiment of the present invention.

FIG. 6 is a cross-sectional view showing a method for manufacturing a semiconductor device according to the first embodiment of the present invention.

FIG. 7 is a cross-sectional view showing a method for manufacturing a semiconductor device according to the first embodiment of the present invention.

FIG. 8 is a cross-sectional view showing a method for manufacturing a semiconductor device according to the first embodiment of the present invention.

FIG. 9 is a cross-sectional view showing a method for manufacturing a semiconductor device according to the first embodiment of the present invention.

FIG. 10 is a cross-sectional view showing a method for manufacturing a semiconductor device according to the first embodiment of the present invention.

FIG. 11 is a cross-sectional view showing a method for manufacturing a semiconductor device according to the first embodiment of the present invention.

FIG. 12 is a cross-sectional view showing a method for manufacturing a semiconductor device according to the first embodiment of the present invention.

FIG. 13 is a graph showing a relationship between a thickness of a c-axis oriented aluminum nitride (AlN) film and an orientation ratio of a crystalline polysilicon (111) on an AlN layer containing the c-axis oriented AlN film in a method for manufacturing the semiconductor device 10 according to the first embodiment of the present invention.

FIG. 14 is a plan view showing a configuration of a display device according to a second embodiment of the present invention.

FIG. 15 is a circuit diagram showing a circuit configuration of a pixel of a display device according to the second embodiment of the present invention.

FIG. 16 is a cross-sectional view showing a cross-sectional structure along a line B1-B2 of the display device shown in FIG. 14.

FIG. 17 is a cross-sectional view showing a cross-sectional structure along a line C1-C2 of the display device shown in FIG. 14.

FIG. 18 is a plan view showing a configuration of a display device according to a third embodiment of the present invention.

FIG. 19 is a circuit diagram showing a circuit configuration of a pixel of a display device according to the third embodiment of the present invention.

FIG. 20 is a plan view showing a configuration of a display device according to a fourth embodiment of the present invention.

### DESCRIPTION OF EMBODIMENTS

Hereinafter, embodiments of the present invention will be described with reference to the drawings and the like. However, the present invention can be implemented in many different ways and is not limited to the description of the embodiments exemplified below. In addition, the drawings may be schematically represented in terms of width, thickness, shape, configuration, etc., compared to the actual embodiment for clarity of explanation, but the drawings are merely examples and do not limit the interpretation of the present invention. Further, in the embodiments of the present invention, elements similar to those previously described with respect to the figures are denoted by the same reference signs (or reference signs with a, b, etc. added after the numbers), and detailed descriptions may be omitted as appropriate. In addition, the terms “first,” “second,” etc., appended to each element are convenient labels used to distinguish each element and have no further meaning unless specifically explained.

In the case where a member or region is to be “on (or under)” another member or region in the present specification, unless otherwise specified, this includes not only the case where it is directly above (or below) the other member or region, but also the case where it is above (or below) the other member or region, that is, it also includes the case where another component is included above (or below) the other member or region.

In the present specification, a direction D1 intersects a direction D2, and a direction D3 intersects the direction D1 and the direction D2 (D1D2 plane). The direction D1 is referred to as a first direction, the direction D2 is referred to as a second direction, and the direction D3 is referred to as a third direction. For example, the direction D1, the direction D2, and the direction D3 correspond to a direction X (direction x), a direction Y (direction y), and a direction Z (direction z). In addition, even if the direction D3 deviates from the vertical with respect to the direction D1 and the direction D2 within the range of error, the direction D3 is considered to be perpendicular to the direction D1 and the direction D2. In this case, for example, it is referred to as approximately vertical.

When the terms “same” and “identical” are used in the present specification, they may include errors within the design range.

### 1. First Embodiment

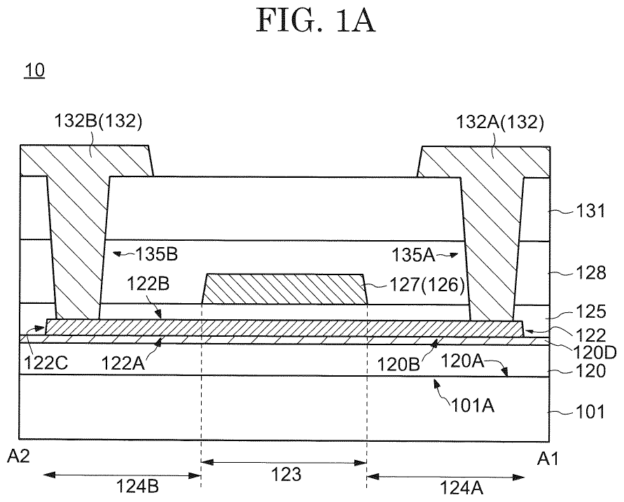

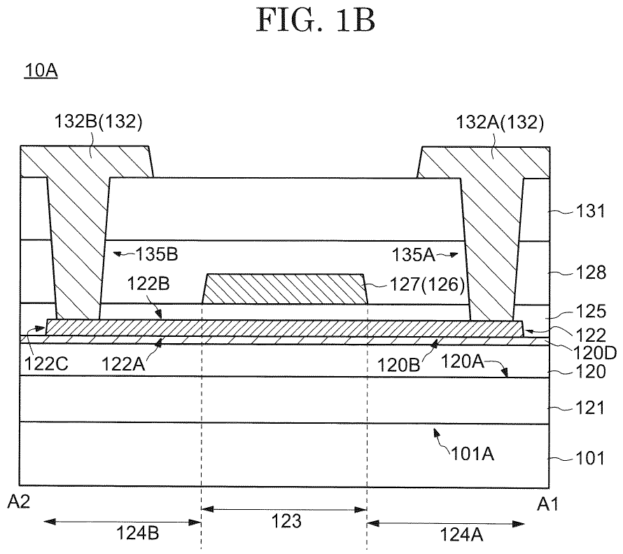

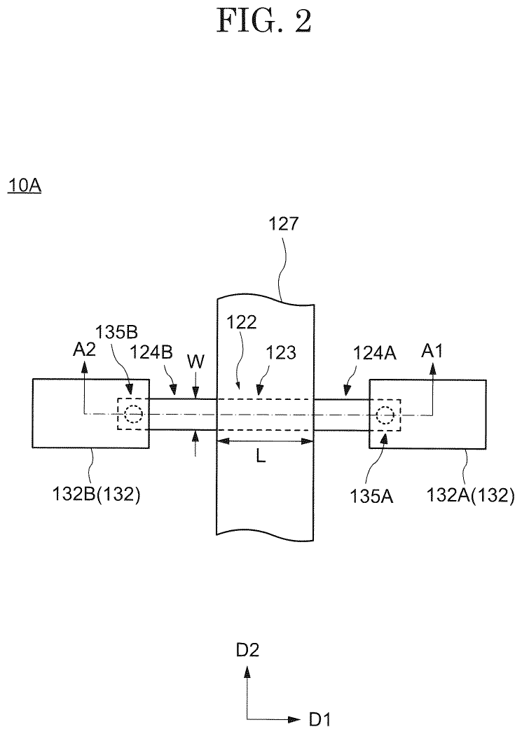

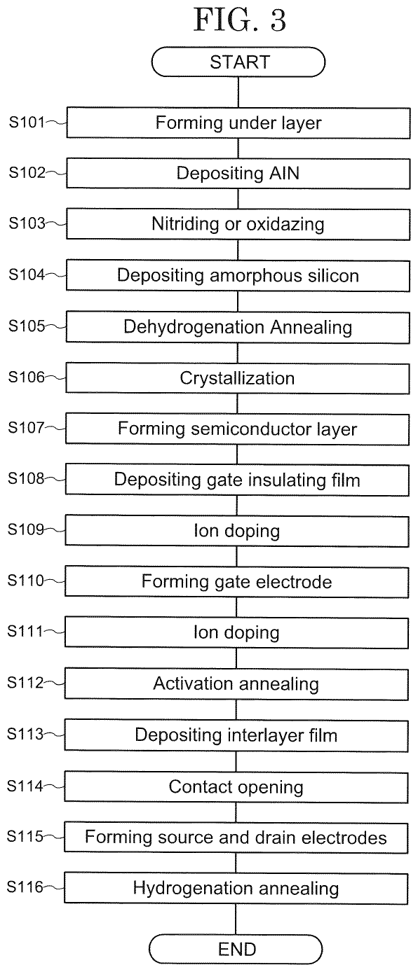

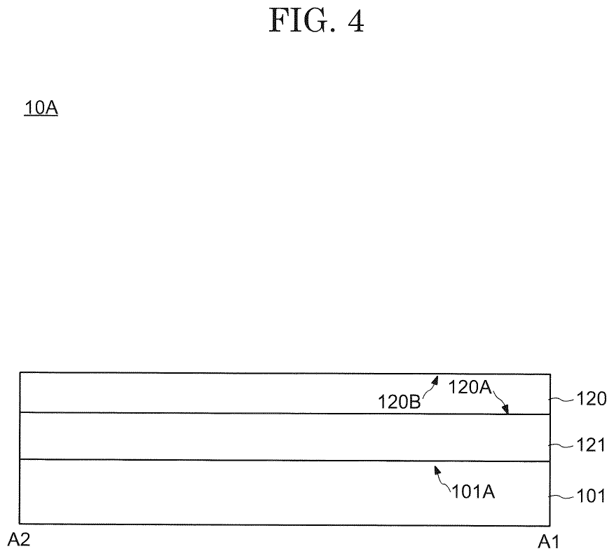

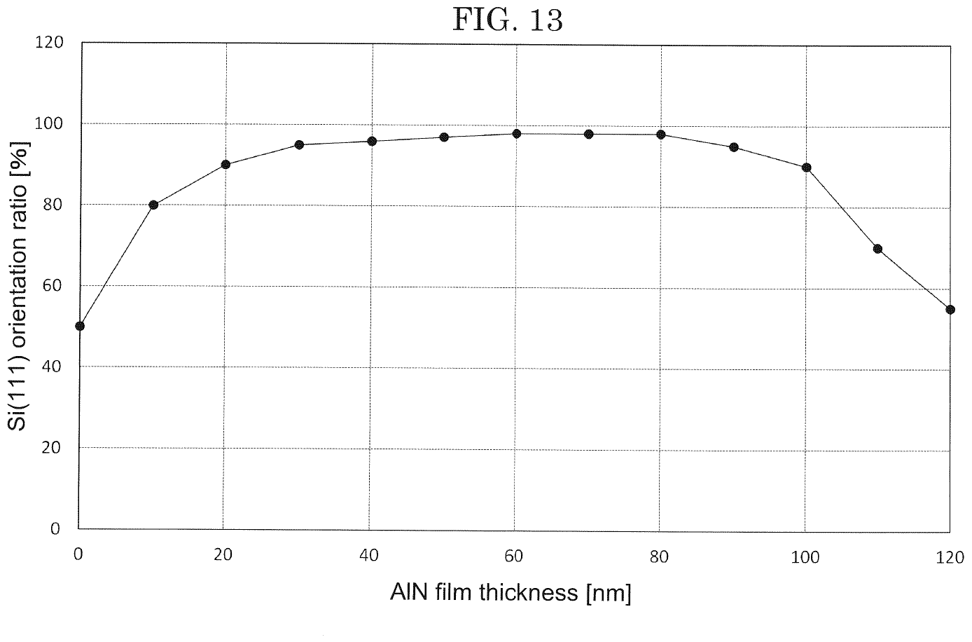

An example of a method for manufacturing a semiconductor device 10 according to a first embodiment will be described with reference to FIG. 1A to FIG. 13. FIG. 1A is a cross-sectional view showing a configuration of the semiconductor device 10 according to an embodiment of the present invention. FIG. 1B is a cross-sectional view showing a configuration of a semiconductor device 10A according to an embodiment of the present invention. FIG. 2 is a plan view showing the configuration of the semiconductor device 10A. In addition, FIG. 1A and FIG. 1B are cross-sectional views showing a cross-sectional structure along a line A1-A2 of FIG. 2. FIG. 3 is a sequence diagram showing a method for manufacturing the semiconductor device 10A shown in FIG. 1B. FIG. 4 to FIG. 12 are cross-sectional views showing a method for manufacturing the semiconductor device 10A. FIG. 13 is a graph showing a relationship between a thickness of a c-axis oriented AlN film and an orientation ratio of a crystalline polysilicon (111) on an AlN layer including the c-axis oriented AlN film in the method for manufacturing the semiconductor device 10A.

For example, the semiconductor device 10 and the semiconductor device 10A include a thin film transistor. For example, the semiconductor device 10 and the semiconductor device 10A are used in a self-luminous display device equipped with a light-emitting element such as an LED, a micro LED, and an EL element. In addition, the semiconductor device 10 and the semiconductor device 10A of the first embodiment are described as including one thin film transistor, but the semiconductor device 10 and the semiconductor device 10A may include a plurality of thin film transistors.

An example of the method for manufacturing the semiconductor device 10A includes forming an under layer 121 (S101) to forming a source electrode and a drain electrode (S115) and performing hydrogen annealing (S116). A direction from a substrate 101 to a source electrode 132A and a drain electrode 132B is referred to as upper or above, and a direction from the source electrode 132A and the drain electrode 132B to the substrate 101 is referred to as lower or below in the description of the first embodiment.

### [1-1. Background of the Invention of Semiconductor Device 10 and Semiconductor Device 10A]

The inventors have been studying a method for manufacturing the semiconductor devices 10 and 10A, which have excellent crystal orientation for forming a semiconductor film forming a transistor and can suppress the deterioration of transistor characteristics due to heat generation in the transistor, and the semiconductor devices 10 and 10A.

For example, the semiconductor devices 10 and 10A include an AlN layer 120 including the c-axis oriented AlN film formed on the substrate 101, and a semiconductor layer 122 containing crystalline polysilicon containing crystalline grains whose (111) planes are oriented parallel to a surface of the AlN layer including the c-axis oriented AlN film. The crystalline polysilicon whose (111) planes are oriented is referred to as the crystalline polysilicon (111) in the first embodiment.

The AlN layer including the c-axis oriented AlN film in the semiconductor devices 10 and 10A, has excellent thermal conductivity, and the crystalline polysilicon (111) formed on the AlN layer including the c-axis oriented AlN film has good orientation.

Although details will be described later, the inventors have found that the semiconductor devices 10 and 10A can suppress the deterioration of characteristics due to heat generation because the crystal orientation of the semiconductor devices 10 and 10A is excellent and the thermal conductivity of the semiconductor devices 10 and 10A is excellent.

### [1-2. Configuration of Semiconductor Device 10 and Semiconductor Device 10A]

As shown in FIG. 1A, the semiconductor device 10 is provided above the substrate 101. The semiconductor device 10 includes the AlN layer 120, the semiconductor layer 122, a gate insulating layer 125, a gate electrode 127, an insulating layer 128, an insulating layer 131, the source electrode 132A, and the drain electrode 132B.

As shown in FIG. 1B, the semiconductor device 10A is provided above the substrate 101. The semiconductor device 10A includes a configuration in which the under layer 121 is added to the configuration of the semiconductor device 10. The under layer 121 is provided to be positioned between a first surface 101A of the substrate 101 and a first surface 120A of the AlN layer 120. The configuration of the semiconductor device 10A is the same as that of the semiconductor device 10 except for the configuration related to the under layer 121. Therefore, the semiconductor device 10A in the description of the first embodiment will be described, and the semiconductor device 10 will be described as necessary.

The semiconductor device 10A includes the under layer 121, the AlN layer 120, the semiconductor layer 122, the gate insulating layer 125, the gate electrode 127, the insulating layer 128, the insulating layer 131, the source electrode 132A, and the drain electrode 132B.

The substrate 101 includes the first surface 101A on the upper surface. The under layer 121 is provided on the first surface 101A of the substrate 101. The under layer 121 functions as a barrier film to shield impurities diffusing from the substrate 101 toward the semiconductor layer 122.

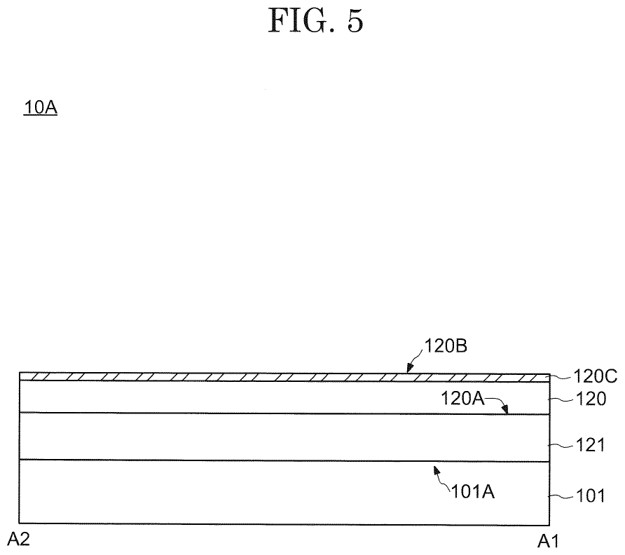

The AlN layer 120 is provided on the under layer 121. The AlN layer 120 includes the c-axis oriented AlN film, the first surface 120A on the lower surface, and a second surface 120B on the upper surface. In addition, the AlN layer 120 includes an oxide layer 120D formed by oxidizing the second surface 120B side, or a nitride layer 120C formed by nitriding the second surface 120B side of the AlN layer 120 (see FIG. 5). The first surface 120A is in contact with the under layer 121. The AlN layer 120 may function as a barrier film to shield impurities diffusing from the substrate 101 toward the semiconductor layer 122.

An example in which the AlN layer 120 includes the oxide layer 120D is described in the description of the semiconductor device 10A.

Further, the AlN layer 120 in the semiconductor device 10 is provided on the first surface 101A of the substrate 101, and the first surface 120A is in contact with the first surface 101A of the substrate 101.

The semiconductor layer 122 contains the crystalline polysilicon (111), a first surface 122A on the lower surface, a second surface 122B on the upper surface, and a third surface 122C on the side surface. The semiconductor layer 122 is provided parallel to the surface (the second surface 120B) of the AlN layer including the c-axis oriented AlN film, and more specifically, the semiconductor layer 122 is provided on the oxide layer 120D included in the AlN layer 120. The first surface 122A on the lower surface is in contact with the second surface 120B of the AlN layer 120. That is, the first surface 122A on the lower surface is parallel to the second surface 120B and in contact with the oxide layer 120D. The semiconductor layer 122 functions as a current path for the transistor. For example, the current path is a source region 124A, a drain region 124B, and a channel region 123.

The semiconductor layer 122 is divided into the source region 124A, the drain region 124B, and the channel region 123. The channel region 123 is a region overlapping the gate electrode 127 and is a region of the semiconductor layer 122 that is vertically below the gate electrode 127. The source region 124A is a region of the semiconductor layer 122 that does not overlap the gate electrode 127 and is a region closer to the source electrode 132A than the channel region 123. The drain region 124B is a region of the semiconductor layer 122 that does not overlap the gate electrode 127 and is closer to the drain electrode 132B than the channel region 123. The semiconductor layer 122 in the channel region 123 exhibits the physical properties of a semiconductor. The semiconductor layer 122 in the source region 124A and the drain region 124B exhibits the physical properties of a conductor.

The gate insulating layer 125 is provided on the second surface 122B and the third surface 122C of the semiconductor layer 122, as well as on the second surface 120B of the AlN layer 120. The gate insulating layer 125 is in contact with the second surface 122B and the third surface 122C of the semiconductor layer 122, as well as with the second surface 120B of the AlN layer 120. That is, the gate insulating layer 125 is in contact with the oxide layer 120D, which is not in contact with the semiconductor layer 122. The gate insulating layer 125 functions as a gate insulating layer in a top-gate transistor.

The gate electrode 127 is provided on the gate insulating layer 125 and faces the second surface 122B of the semiconductor layer 122. The gate electrode 127 functions as a top gate of the semiconductor device 10 and as a light-shielding film to suppress the influence of light on the semiconductor layer 122. The gate electrode 127 is one of the wirings or electrodes included in a conductive layer 126. When not distinguishing between wirings, electrodes, and the gate electrode 127, they are collectively referred to as the conductive layer 126, and when distinguishing, wirings, electrodes, and the gate electrode 127, they are referred to by the names of each wiring and each electrode.

The insulating layer 128 and the insulating layer 131 are provided on the gate insulating layer 125 and the gate electrode 127. Openings 135A and 135B reaching the semiconductor layer 122 are provided in the insulating layer 128 and the insulating layer 131. The insulating layer 128 and the insulating layer 131 have a function of insulating the gate electrode 127 from the source electrode 132A and a function of insulating the gate electrode 127 from the drain electrode 132B.

The source electrode 132A is provided inside the opening 135A. The source electrode 132A is in contact with the source region 124A of the semiconductor layer 122 at the bottom of the opening 135A. The drain electrode 132B is provided inside the opening 135B. The drain electrode 132B is in contact with the drain region 124B of the semiconductor layer 122 at the bottom of the opening 135B. The source electrode 132A and the drain electrode 132B have a function of supplying a voltage to the semiconductor device 10A.

When not specifically distinguishing between the source electrode 132A and the drain electrode 132B, they may be collectively referred to as a conductive layer 132. The functions of the source electrode 132A and the drain electrode 132B as a source and a drain may switch depending on the supplied voltage.

As shown in FIG. 2, the direction D1 in a plan view of the semiconductor device 10A is the direction connecting the source electrode 132A and the drain electrode 132B, indicating a channel length L of the semiconductor device 10. Specifically, a length in the direction D1 of the region where the semiconductor layer 122 and the gate electrode 127 overlap (the channel region 123) is the channel length L, and a width in the direction D2 of the channel region 123 is a channel width W.

In a plan view of the semiconductor device 10A shown in FIG. 2, a configuration where the source electrode 132A and the drain electrode 132B do not overlap the gate electrode 127 is exemplified, but the configuration of the source electrode 132A and the drain electrode 132B is not limited to the configuration shown here. For example, in a plan view of the semiconductor device 10A, at least one of the source electrode 132A and the drain electrode 132B may overlap the gate electrode 127.

### [1-3. Materials Used in Semiconductor Device 10 and Semiconductor Device 10A]

A rigid substrate with light transmittance, such as a glass substrate, a quartz substrate, or a sapphire substrate, is used as the substrate 101. In the case where the semiconductor device 10 and the semiconductor device 10A are used in a top-emission type self-luminous display device, the substrate 101 does not need to be transparent, so the substrate 101 may contain impurities that degrade the transparency of the substrate 101.

A general insulating material is used as a material for forming the under layer 121. For example, the insulating material may include silicon oxide (SiOₓ), silicon oxynitride (SiOₓN_{y}), silicon nitride (SiNₓ), silicon oxynitride (SiNₓO_{y}), aluminum oxide (AlOₓ), aluminum oxynitride (AlOₓN_{y}), aluminum oxide nitride (AlNₓO_{y}), aluminum nitride (AlNₓ), etc.

As shown in Table 1 below, the melting point of AlN contained in the AlN layer 120 is higher than that of silicon (Si). Therefore, the AlN layer 120 including the AlN film does not dissolve during annealing (see S106 in FIG. 3) for the crystallization of polysilicon. In addition, as shown in Table 1 below, the coefficient of thermal expansion (CTE) of AlN contained in the AlN layer 120 is approximately the same as the CTE of glass. Therefore, the AlN layer 120 including the c-axis oriented AlN film has a small distortion due to heat after annealing. That is, the AlN layer 120 including the c-axis oriented AlN film is excellent in thermal conductivity and heat resistance. As a result, the semiconductor device 10 and the semiconductor device 10A including the AlN layer 120 including the c-axis oriented AlN film can suppress the deterioration of transistor characteristics due to heat generation in the transistor.

TABLE 1

| Material | Glass | AIN | Si | GaN |
|---|---|---|---|---|
| CTE ppm [1/K] | 3.5~3.9 | 4.2 | 2.6 | 5.6 |
| Thermal conductivity | 0.15~0.16 | 2.85 | 1.5 | 1.3 |
| [W/m · K] | | | | |
| Melting point [K] | >1223 | 3273 | 1687 | 2773 |

A material forming the semiconductor layer 122 contains the crystalline polysilicon (111). Silicon formed on the AlN layer including the c-axis oriented AlN film tends to be oriented in the (111) direction. That is, the crystalline polysilicon (111) is easily formed on the AlN layer including the c-axis oriented AlN film. As a result, the semiconductor device 10 and the semiconductor device 10A containing the crystalline polysilicon (111) containing crystal grains formed parallel to the surface of the AlN layer including the c-axis oriented AlN film include crystals with excellent orientation and can suppress the deterioration of transistor characteristics due to heat generation in the transistor. Therefore, by using the semiconductor device 10 and the semiconductor device 10A containing the crystalline polysilicon (111) containing crystal grains formed parallel to the surface of the AlN layer including the c-axis oriented AlN film, it is possible to obtain good initial characteristics and good Iong-term reliability with less variation in transistor characteristics.

An insulating material containing oxygen among the above insulating materials is used as the material for forming the gate insulating layer 125. For example, the material for forming the gate insulating layer 125 includes silicon oxide (SiOₓ), silicon oxynitride (SiOₓN_{y}), aluminum oxide (AlOₓ), aluminum oxynitride (AlOₓN_{y}), etc.

A general metal material is used as a material for forming the gate electrode 127. For example, the metal material includes aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy or compound thereof. The metal material forming the gate electrode 127 and the conductive layer 132 may be used in a single layer or a stacked layer.

A general insulating material and configuration may be used for the insulating layer 128, similar to those forming the under layer 121.

The insulating layer 131 can be made of an organic compound material selected from acrylic, polyimide, and the like, which has excellent surface flatness. The insulating layer 131 covers unevenness caused by elements such as transistors and capacitance elements, and the surface of the insulating layer 131 becomes flat.

A general metal material and configuration is used for a material forming the conductive layer 132, similar to those forming the gate electrode 127.

### [1-4. Method for Manufacturing Semiconductor Device 10A]

The method for manufacturing the semiconductor device 10A will be described with reference to FIG. 1B, and FIG. 3 to FIG. 13. In this case, a manufacturing method will be described in which an oxidation process is performed after forming the AlN layer 120, and an n-type thin film transistor is formed. If necessary, a manufacturing method will be described in which a nitriding process is performed after forming the AlN layer 120 and a p-type thin-film transistor is formed. Descriptions of the same or similar configurations as those in FIG. 1A, FIG. 1B, and FIG. 2 will be omitted here.

As shown in FIG. 3 and FIG. 4, the under layer 121 is formed on the first surface 101A of the substrate 101 (see “Forming Under Layer” in step S101 of FIG. 3). The under layer 121 is formed by a CVD (Chemical Vapor Deposition) method. For example, a material forming the under layer 121 is silicon nitride. For example, the under layer 121 can block impurities diffusing from the substrate 101 side toward the semiconductor layer 122.

As shown in FIG. 3 and FIG. 4, when the method for manufacturing semiconductor device 10A is started (START), the AlN layer 120 is deposited on the under layer 121 (see “Depositing AlN” in step S102 of FIG. 3). For example, the AlN layer 120 is deposited by a sputtering method. As described in the section “1-1. Background of the Invention of Semiconductor Device 10 and Semiconductor Device 10A” to the section “1-3. Materials Used in Semiconductor Device 10 and Semiconductor Device 10A”, the AlN layer 120 includes the c-axis oriented AlN film. The AlN layer 120 has excellent thermal conductivity and heat resistance. As a result, the semiconductor device 10A including the AlN layer 120 dissipates heat generated by the semiconductor layer 122 to the outside of the semiconductor device 10A, and has high resistance to the heat generated by the semiconductor layer 122.

In addition, as described in the section “1-2. Configuration of Semiconductor Device 10 and Semiconductor Device 10A”, the semiconductor device 10 does not include the under layer 121 and includes the AlN layer 120 formed on the first surface 101A of the substrate 101. In this case, the method for manufacturing the semiconductor device 10 does not include forming the under layer 121, but includes forming the AlN layer 120 to be in contact with the first surface 101A of the substrate 101 without forming the under layer 121.

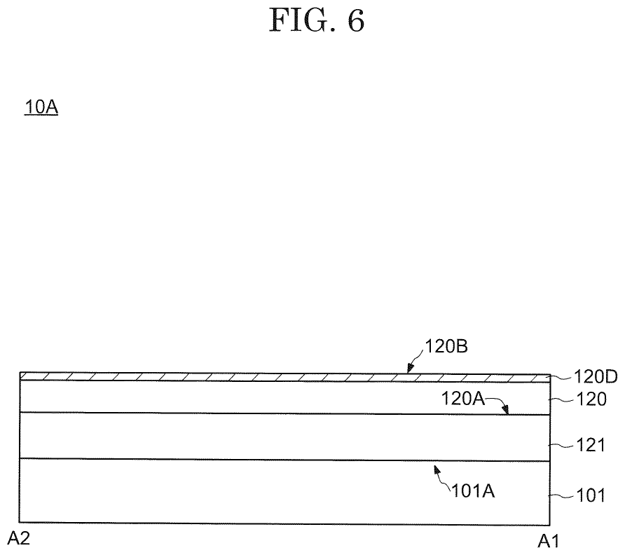

As shown in FIG. 3, FIG. 5, or FIG. 6, the second surface 120B side of the upper surface of the AlN layer 120 is nitrided or oxidized (see “Nitriding or Oxidizing” in step S103 of FIG. 3). The process in step S103 is a process for passivating the surface of the AlN layer 120. For example, the process in step S103 includes a nitriding process or an oxidation process.

Specifically, the nitriding process includes heat treating (annealing) the surface of the AlN layer 120 with a nitrogen-containing gas, or treating the surface of the AlN layer 120 with a nitrogen-containing plasma. Through the nitriding process in step S103, a dangling bond on the surface of the AlN layer 120 bonds with a nitrogen atom, the surface of the AlN layer 120 is passivated, and the nitride layer 120C (see FIG. 5) is formed on the second surface 120B side of the upper surface of the AlN layer 120. As a result, the surface of the AlN layer 120, including grain boundaries, is stabilized. The concentration of nitrogen contained in the nitride layer 120C is higher than the concentration of nitrogen contained in the AlN layer between the nitride layer 120C and the first surface 120A on the lower surface.

In addition, specifically, the oxidation process includes heat treating (annealing) the surface of the AlN layer 120 with an oxygen-containing gas, or treating the surface of the AlN layer 120 with an oxygen-containing plasma. For example, the oxygen-containing gas is a gas including an oxygen gas (O₂ gas), an ozone gas (O₃ gas), or a nitrogen oxide gas (N₂O gas). For example, the oxygen-containing plasma is a plasma based on the oxygen gas (O₂ gas), the ozone gas (O₃ gas), or the nitrogen oxide gas (N₂O gas). Through the oxidation process in step S103, a dangling bond on the surface of the AlN layer 120 bonds with an oxygen atom, the surface of the AlN layer 120 is passivated, and the oxide layer 120D (see FIG. 6) is formed on the second surface 120B side of the upper surface of the AlN layer 120. As a result, the surface of the AlN layer 120, including grain boundaries, is stabilized. The concentration of oxygen contained in the oxide layer 120D is higher than the concentration of oxygen contained in the AlN layer between the oxide layer 120D and the first surface 120A on the lower surface.

As shown in Table 2 below, considering the standard Gibbs energy of formation of AlN and aluminum oxide (Al₂O₃), aluminum easily forms nitrides and oxides, and the formed aluminum nitride or aluminum oxide is stable. Therefore, the second surface 120B side of the upper surface of the AlN layer 120 including the c-axis oriented AlN film is passivated by nitriding or oxidizing, and the surface of the AlN layer 120, including the grain boundaries, is stabilized. In addition, for example, considering the standard Gibbs energy of formation of aluminum oxide (Al2O3), aluminum oxide formed by oxidation is stable in a reducing gas atmosphere. Therefore, in a silane (SiH₄) gas atmosphere during “Depositing Amorphous Silicon” in step S104 described later, the nitrided or oxidized AlN layer 120 is stable without reacting with, for example, SiH₄ gas. Further, since the nitridation or oxidation of the AlN layer 120 occurs at the surface and grain boundaries of the AlN layer 120, the orientation of the AlN layer 120 including the c-axis oriented AlN film is not significantly disrupted. Therefore, the orientation of the crystalline polysilicon (111) formed on the AlN layer 120 including the c-axis oriented AlN film is almost unaffected.

TABLE 2

| | | Standard Gibbs |
|---|---|---|
| | | energy of formation |
| Material | state | [kJ/mol] |
| AIN | c | −287 |
| Al₂O₃(α, corundum) | c1 | −1582.31 |
| Al₂O₃(γ) | c2 | −1563.9 |

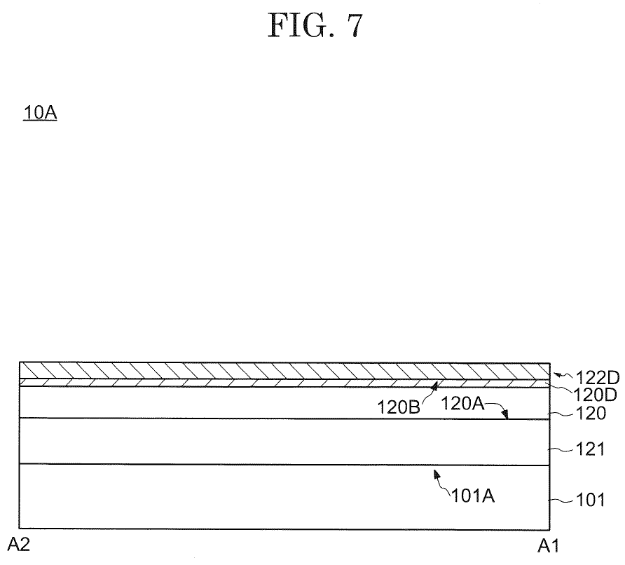

As shown in FIG. 3 and FIG. 7, an amorphous silicon layer 122D including an amorphous silicon film is deposited (see “Amorphous Silicon Deposition” in step S104 of FIG. 3). The amorphous silicon layer 122D is deposited by a plasma CVD method or sputtering method. For example, the amorphous silicon layer 122D in the first embodiment is formed by the plasma CVD method using SiH₄ gas as a material. Next, dehydrogenation annealing is performed to reduce the hydrogen contained in the amorphous silicon layer 122D (see “Dehydrogenation Annealing” in step S105 of FIG. 3).

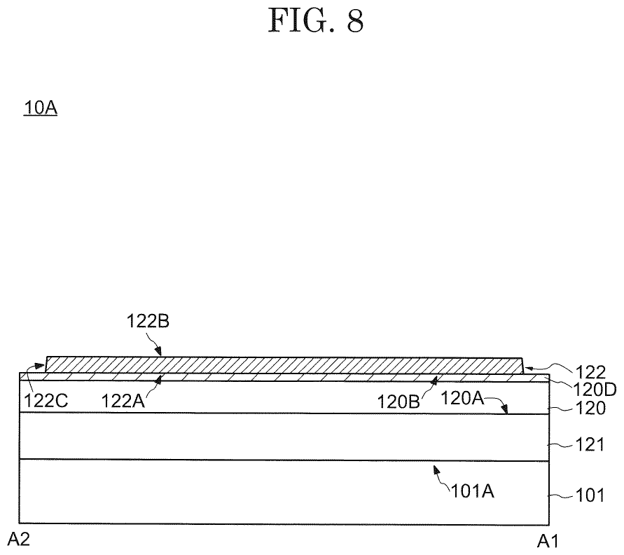

As shown in FIG. 3 and FIG. 8, the amorphous silicon layer 122D is crystallized to form the semiconductor layer 122 containing the crystalline polysilicon (111) containing crystal grains whose (111) planes are preferentially oriented parallel to the surface of the AlN layer 120 including the c-axis oriented AlN film (see “Crystallization” in step S106 of FIG. 3 and “Forming Semiconductor Layer” in step S107 of FIG. 3). Although details will be described later, the (111) planes are preferentially oriented parallel to the surface of the AlN layer 120 including the c-axis oriented AlN film, which means, for example, that the orientation ratio of the crystalline polysilicon (111) on the AlN layer 120 (Si (111) orientation ratio [%]) is 80% or more. The process in step S106 includes crystallizing the amorphous silicon layer 122D using a laser annealing method. Specifically, the process in step S106 includes crystallizing amorphous silicon into the crystalline polysilicon (111) using an excimer laser annealing method. In addition, the method for manufacturing the semiconductor device 10 and the semiconductor device 10A forms the crystalline polysilicon (111) containing crystal grains whose (111) planes are oriented parallel to the surface of the AlN layer including the c-axis oriented AlN film, so the number of laser irradiations using the excimer laser annealing method can be less than 10 times, fewer than conventional examples. In addition, for example, the excimer laser annealing is used for the laser annealing in the first embodiment, but the laser annealing is not limited to the excimer laser annealing. The laser annealing may also be annealing using a solid-state laser (solid-state laser annealing). For example, the solid-state laser may be a semiconductor laser or a fiber laser.

In the case of using the excimer laser annealing method known in the technical field of manufacturing methods of transistors used in a display device, there are problems such as large variations in the transient characteristics of the transistors, a decrease in the tact due to tens of laser irradiations on the amorphous silicon layer, and the deterioration of transistor characteristics due to heat generation in the transistor. On the other hand, the method for manufacturing the semiconductor device 10 and the semiconductor device 10A includes forming the crystalline polysilicon (111) on the AlN layer including the c-axis oriented AlN film, so that each of the variations in the transient characteristics of the transistors, the decrease in the tact due to laser irradiation, and the deterioration of transistor characteristics due to heat generation in the transistor can be suppressed.

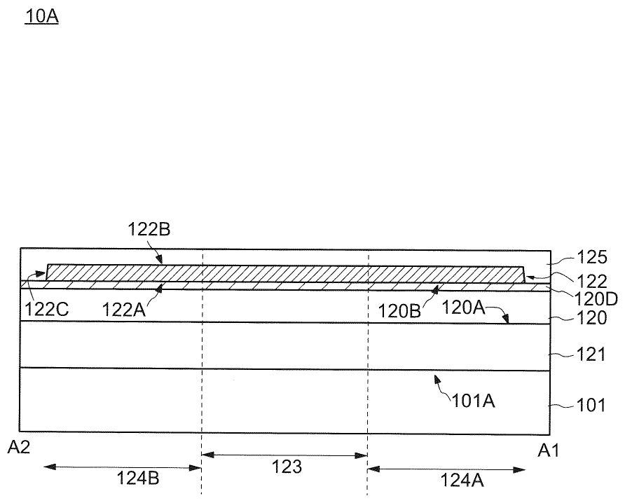

The process in step S107 includes forming the semiconductor layer 122 containing the crystalline polysilicon (111) on the AlN layer including the c-axis oriented AlN film using a photolithography technique. The semiconductor layer 122 includes a plurality of island-shaped portions formed to fit the semiconductor device 10A. Each island-shaped portion includes the source region 124A (see FIG. 3 and FIG. 9), the drain region 124B (see FIG. 3 and FIG. 9), and the channel region 123 (see FIG. 3 and FIG. 9) of each semiconductor device 10A.

As shown in FIG. 3 and FIG. 9, the gate insulating layer 125 is formed on the semiconductor layer 122 containing the crystalline polysilicon (111) (see “Depositing Gate Insulating Film” in step S108 of FIG. 3). For example, a material forming the gate insulating layer 125 is silicon oxide (SiOₓ). The gate insulating layer 125 is formed by the CVD method. The gate insulating layer 125 may be referred to as a “first insulating layer.”

As shown in FIG. 3 and FIG. 9, the semiconductor layer 122 containing the crystalline polysilicon (111) is doped with impurities (see “Ion Doping” in step S109 of FIG. 3). For example, the process in step S109 includes forming a resist to cover the channel region 123 using a photomask and an exposure device using the photolithography technique, and doping impurity ions into the source region 124A and the drain region 124B. In this case, since the method for manufacturing the n-type thin-film transistor is described, phosphorus (P) ions are doped into the source region 124A and the drain region 124B from the gate insulating layer 125 toward the substrate 101. Impurities are not injected into the semiconductor layer 122 that functions as the channel region 123 of the semiconductor device 10.

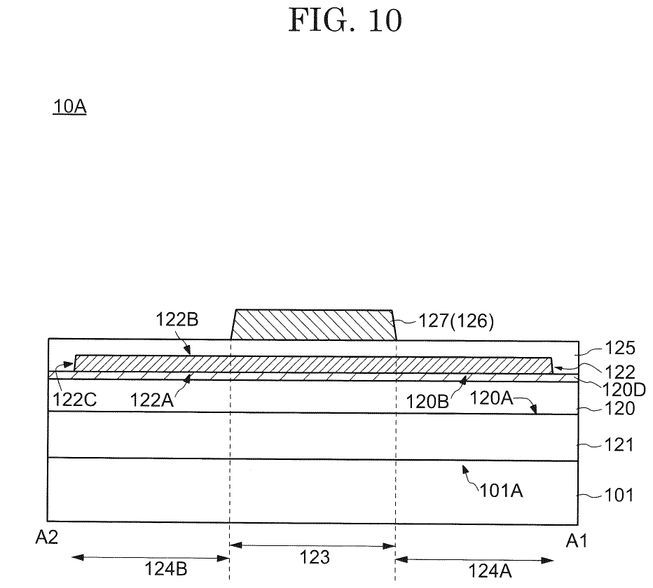

As shown in FIG. 3 and FIG. 10, the gate electrode 127 is formed on the gate insulating layer 125 (see “Forming Gate Electrode” in step S110 of FIG. 3). For example, the process in step S110 includes depositing a material for forming the gate electrode 127 on the gate insulating layer 125 by the sputtering method, and forming the gate electrode 127 using the photolithography technique. The gate electrode 127 is in contact with the gate insulating layer 125. The gate electrode may be referred to as a “first electrode”.

With the gate electrode 127 formed, the semiconductor layer 122 containing the crystalline polysilicon (111) is doped with impurities (see “Ion doping” in step S111 of FIG. 3). For example, the process in step S110 includes forming a resist to cover the semiconductor layer 122 doped with P ions by “Ion doping” in step S111 using the photomask and the exposure device using the photolithography technique. In addition, the process in step S110 includes doping impurity ions into the source region 124A and the drain region 124B of the semiconductor layer 122, which are different from the source region 124A and the drain region 124B of the semiconductor layer 122 doped with P ions by “Ion doping” in step S109. Boron (B) ions in the process in step S110 are doped into the source region 124A and the drain region 124B of the semiconductor layer 122, which are different from the source region 124A and the drain region 124B of the semiconductor layer 122 doped with P ions by “Ion doping” in step S109, from the gate insulating layer 125 toward the substrate 101.

In addition, the order of processes in steps S109, S110, and S111 is an example and is not limited to the order described here. For example, the order of the processes may be step S111, step S110, step S109, or step S110, step S109, step S111. The method for manufacturing the semiconductor device 10A includes doping the semiconductor layer 122 with two types of ions having different polarities and forming the gate electrode, and the order of the processes may be random.

After the processes of step S109, step S110, and step S111, a heat treatment is performed to activate the impurities contained in the semiconductor layer 122 (see “Activation annealing” in step S112 of FIG. 3). By activating the impurities contained in the semiconductor layer 122, a resistance value of the semiconductor layer 122 can be reduced. Specifically, the resistance values of the source region 124A and the drain region 124B can be reduced below the resistance values of the source region 124A and the drain region 124B in step S111.

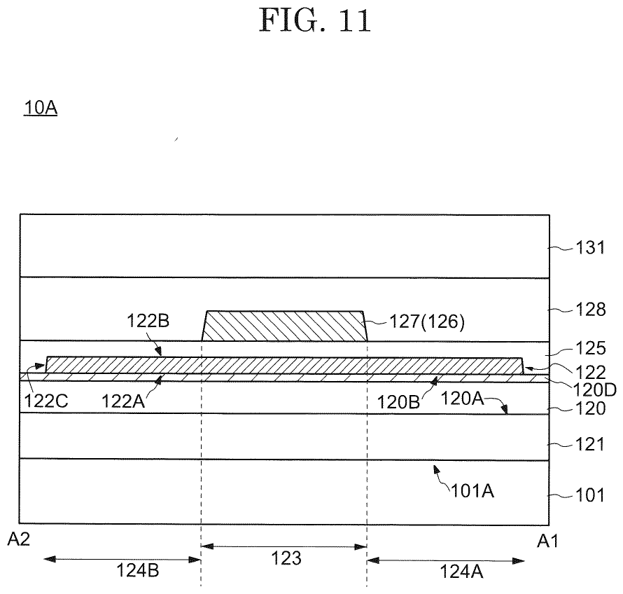

As shown in FIG. 3 and FIG. 11, the insulating layer 128 and the insulating layer 131 are deposited as interlayer films on the gate insulating layer 125 and the gate electrode 127 (see “Depositing interlayer film” in step S113 of FIG. 3). For example, a material forming the insulating layer 128 is silicon oxide (SiOₓ). For example, a material forming the insulating layer 131 is polyimide or acrylic resin. The insulating layer 128 is deposited by the CVD method, and the insulating layer 131 is formed by a wet deposition method such as an inkjet method or a spin coating method. In one example of the process in step S113, two insulating layers are formed, but three or more insulating layers may be formed. In addition, a conductive layer may be formed between the gate insulating layer 125 and the gate electrode 127. The insulating layer 128 may be referred to as a “second insulating layer”. The insulating layer 131 may be referred to as a “third insulating layer”.

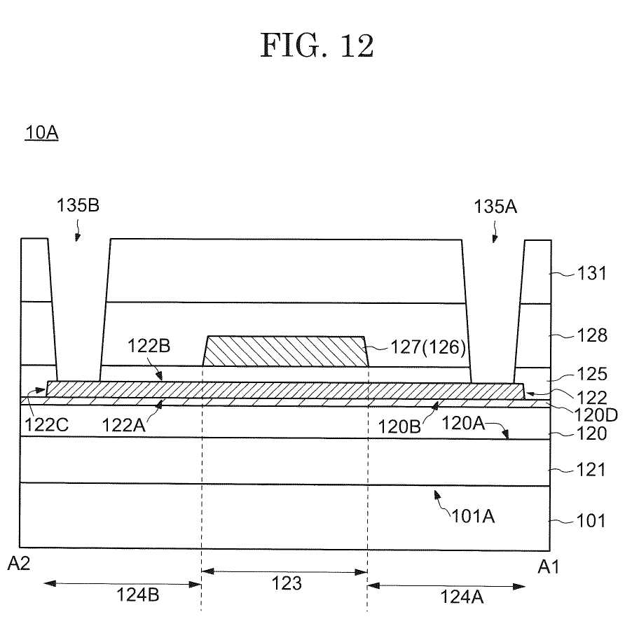

As shown in FIG. 3 and FIG. 12, the openings 135A and 135B are formed in the gate insulating layer 125, the insulating layer 128, and the insulating layer 131 (see “Contact opening” in step S114 of FIG. 3). The semiconductor layer 122 in the source region 124A is exposed by the opening 135A. The semiconductor layer 122 in the drain region 124B is exposed by the opening 135B.

As shown in FIG. 3 and FIG. 1B, the conductive layer 132 (the source electrode 132A and the drain electrode 132B) is formed on the exposed semiconductor layer 122, the side of the insulating layer 128, and the side surface and the upper surface of the insulating layer 131 by the openings 135A and 135B (see “Forming source and drain electrodes” in step S115 of FIG. 3). For example, the process in step S115 includes depositing the materials for forming the source electrode 132A and the drain electrode 132B on the upper surface of the semiconductor layer 122, the side surface of the insulating layer 128, and the side surface and the upper surface of the insulating layer 131 by the sputtering method, and forming the source electrode 132A and the drain electrode 132B using the photolithography technique. The source electrode 132A and the drain electrode 132B are in contact with the upper surface of the semiconductor layer 122, the side surface of the insulating layer 128, and the side surface and the upper surface of the insulating layer 131. The source electrode 132A and the drain electrode 132B may be referred to as the “second electrode” and the “third electrode”.

As shown in FIG. 3, a hydrogenation heat treatment is performed (see “Hydrogenation annealing” in step S116 of FIG. 3). For example, the process in step S116 includes terminating a dangling bond of the crystalline polysilicon (111) with hydrogen.

Step S116 can suppress the reaction of the second surface 122B (upper surface) and the third surface 122C (side surface) of the crystalline polysilicon (111) with oxygen or impurities, and the adhesion of oxygen or impurities to the second surface 122B (upper surface) and the third surface 122C (side surface) of the crystalline polysilicon (111). As a result, step S116 can suppress the oxidation and contamination of the second surface 122B (upper surface) and the third surface 122C (side surface) of the crystalline polysilicon (111). That is, step S116 can suppress the deterioration of the characteristics of the semiconductor device 10A due to the oxidation and contamination of the semiconductor layer 122.

When the processes from step S101 to step S116 are completed (END), the semiconductor device 10A shown in FIG. 1B is completed.

[1-5. Relationship Between the Thickness of c-Axis Oriented AlN Film and the Orientation Ratio of the Crystalline Polysilicon (111) on the AlN Layer]

A relationship between the thickness of the c-axis oriented AlN film and the orientation ratio of the crystalline polysilicon (111) on the AlN layer including the c-axis oriented AlN film in the method for manufacturing the semiconductor device 10A will be described with reference to FIG. 13 and Table 3 below. Descriptions of the same or similar configurations as those in FIG. 1A and FIG. 1B to FIG. 12 will be omitted here.

Table 3 below shows a relationship between the thickness of the c-axis oriented AlN film (AlN film thickness [nm]) and the orientation ratio of the crystalline polysilicon (111) on the AlN layer including the c-axis oriented AlN film (Si (111) orientation ratio [%]). FIG. 13 is a plot diagram plotting the Si (111) orientation ratio against the AlN film thickness shown in Table 3.

TABLE 3

| AIN film | Si(111) | |
|---|---|---|
| thickness | orientation | |
| [nm] | ratio [%] | remarks |
| 0 | 50 | (100) orientation |
| 10 | 80 | improved thermal |
| | | conductivity |
| 20 | 90 | improved thermal |
| | | conductivity |
| 30 | 95 | improved thermal |
| | | conductivity |
| 40 | 96 | improved thermal |
| | | conductivity |
| 50 | 97 | improved thermal |
| | | conductivity |
| 60 | 98 | improved thermal |
| | | conductivity |
| 70 | 98 | improved thermal |
| | | conductivity |
| 80 | 98 | improved thermal |
| | | conductivity |
| 90 | 95 | improved thermal |
| | | conductivity |
| 100 | 90 | improved thermal |
| | | conductivity |
| 110 | 70 | further improved |
| | | thermal conductivity |
| 120 | 55 | further improved |
| | | thermal conductivity |

According to FIG. 13 and Table 3, when the AlN film thickness is 10 nm or more and 104 nm or less, the Si (111) orientation ratio is 80% or more, and the crystalline polysilicon (111) containing crystal grains whose (111) planes are oriented parallel to the surface of the AlN layer including the AlN film can be formed stably. In addition, when the AlN film thickness is 20 nm or more and 100 nm or less, the Si (111) orientation ratio is 90% or more, and the crystalline polysilicon (111) containing crystal grains whose (111) planes are oriented parallel to the surface of the AlN layer including the c-axis oriented AlN film can be formed more stably.

As shown in the remarks in Table 3, when the AlN film thickness is 0 nm without the formation of the AlN layer 120 including the c-axis oriented AlN film, the Si (111) orientation ratio is 50%, and polysilicon is also oriented in (100). In addition, when the AlN film thickness is 110 nm or more, the Si (111) orientation ratio is less than 80%, but the thermal conductivity is good. That is, according to FIG. 13 and Table 3, by increasing the AlN film thickness, the thermal conductivity of the AlN layer 120 including the c-axis oriented AlN film becomes better.

### 2. Second Embodiment

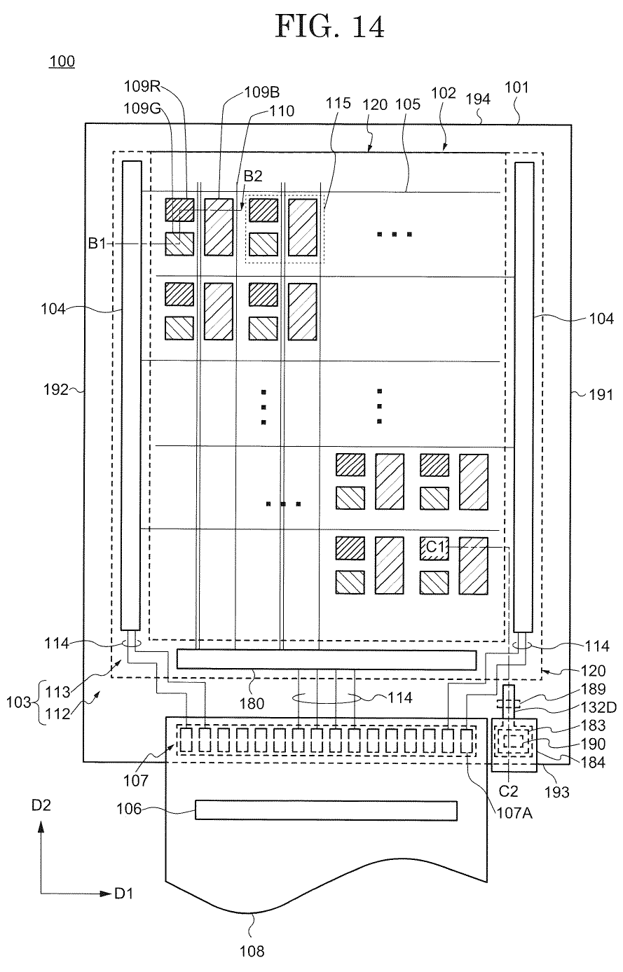

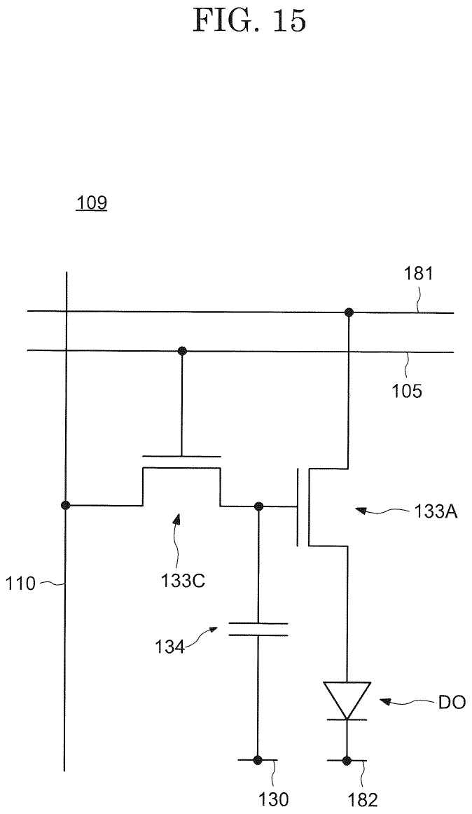

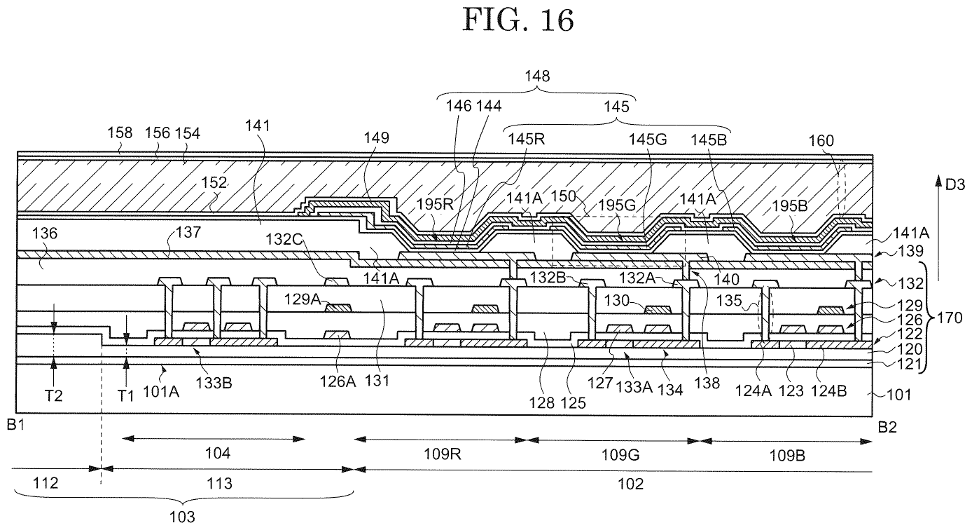

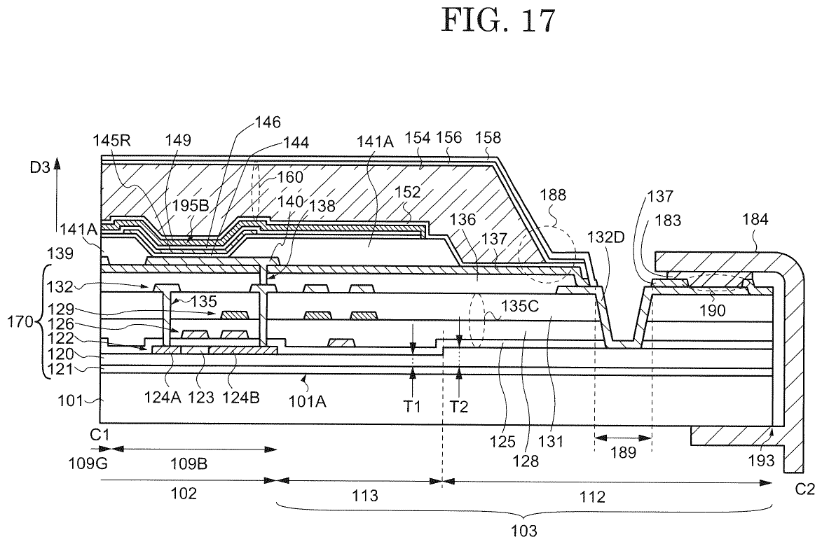

A display device 100 including the semiconductor device 10A according to a second embodiment will be described with reference to FIG. 14 to FIG. 17. In an example shown in the second embodiment, the display device 100 including the semiconductor device 10A is an organic EL display device. FIG. 14 is a plan view showing a configuration of the display device 100 according to an embodiment of the present invention. FIG. 15 is a circuit diagram showing a circuit configuration of a subpixel 109 included in a pixel 115 of the display device 100. FIG. 16 is a cross-sectional view showing a cross-sectional structure along a line B1-B2 of the display device 100 shown in FIG. 14. FIG. 17 is a cross-sectional view showing a cross-sectional structure along a line C1-C2 of the display device shown in FIG. 14. Descriptions of the same or similar configurations as those in FIG. 1A and FIG. 1B to FIG. 13 will be omitted here.

### [2-1. Configuration of Display Device 100]

The configuration of the display device 100 will be described with reference to FIG. 14. As shown in FIG. 14, for example, the display device 100 includes a display region 102 and a peripheral region 103 on the first surface 101A of the substrate 101. The substrate 101 includes a first side 191, a second side 192 opposite to the first side, a third side 193, and a fourth side 194 opposite to the third side. In a plan view, the display region 102 and the peripheral region 103 are surrounded by the first side 191, the second side 192 opposite to the first side, the third side 193, and the fourth side 194 opposite to the third side.

A plurality of pixels 115 in the display region 102 is arranged in a matrix in the direction D1 and the direction D2.

The pixel 115 includes a subpixel 109R, a subpixel 109G, and a subpixel 109B. The subpixels 109R and 109B are arranged side by side in the direction D1. The subpixels 109G and 109B are arranged side by side in the direction D1. The subpixels 109R and 109G are arranged side by side in the direction D2. A plurality of subpixels 109B is arranged side by side in the direction D2. That is, in the display region 102, a column where the subpixels 109R and 109G are alternately arranged and a column where only the subpixel 109B is arranged are alternately arranged in the direction D1 (row direction).

In the case where the subpixels are not distinguished from one another, the subpixel is expressed as the subpixel 109. In the case where the subpixels are distinguished from one another, the subpixels are expressed as the subpixel 109R, the subpixel 109G, and the subpixel 109B, respectively.

For example, the subpixel 109R includes a light-emitting layer 145R (see FIG. 16) that emits red light and includes a red light-emitting element. The subpixel 109G includes a light-emitting layer 145G (see FIG. 16) that emits green light and includes a green light-emitting element. The subpixel 109B includes a light-emitting layer 145B (see FIG. 16) that emits blue light and includes a blue light-emitting element. A component included in the red light-emitting element is indicated by R (red), a component in the green light-emitting element is indicated by G (green), and a component in the blue light-emitting element is indicated by B (blue), in the second embodiment. For example, an emission peak wavelength of the blue light-emitting element is 460 nm or more and 500 nm or less. An emission peak wavelength of the red light-emitting element is 610 nm or more and 780 nm or less. The emission peak wavelength of the green light-emitting element is 500 nm or more and 570 nm or less.

The peripheral region 103 surrounds the display region 102. A scanning signal line drive circuit 104 is arranged near each of the first side 191 and the second side 192 in the peripheral region 103. In addition, a terminal portion 107, a wiring 132D, a connecting wiring 183, and a metal member 184 of a housing are arranged near the third side 193. A video signal line driving circuit 180 is arranged between the terminal portion 107 and the display region 102. The display region 102 is referred to as a first region, a region of the peripheral region 103 that includes an AlN layer thicker than the AlN layer overlapping the first region is referred to as a second region, and a region of the peripheral region 103 that includes an AlN layer that is the same thickness as the AlN layer in the first region is referred to as a third region.

The terminal portion 107 includes a plurality of terminals 107A. The plurality of terminals 107A is arranged adjacent to the display region 102 in the second direction D2 (column direction).

A flexible printed circuit board 108 is connected to the terminal portion 107. A driver IC 106 is arranged on the flexible printed circuit board 108 using a COF (Chip on Film) method. The driver IC 106, the video signal line driving circuit 180, and the scanning signal line drive circuit 104 in the second embodiment may be collectively referred to as a control circuit or a control unit.

For example, a plurality of connecting wirings 114 is connected to the plurality of terminals 107A. The connecting wiring 114 may be electrically connected to the plurality of pixels 115.

The plurality of connecting wirings 114 and a plurality of scanning signal lines 105 is connected to the scanning signal line drive circuit 104. The plurality of scanning signal lines 105 is arranged adjacent to each other in the first direction D1 (row direction) in the display device 100. The scanning signal line drive circuit 104 is provided at a position adjacent to the display region 102 in the first direction D1. The plurality of scanning signal lines 105 is electrically connected to the plurality of pixels 115.

The plurality of connecting wirings 114 and a plurality of video signal lines 110 are connected to the video signal line driving circuit 180. The plurality of video signal lines 110 is arranged to extend in the second direction D2 (column direction) in the display device 100. The plurality of video signal lines 110 is electrically connected to the plurality of pixels 115. The video signal line driving circuit 180 may include a multiplexer circuit for selecting a video signal.

The driver IC 106 supplies a signal (voltage) to the scanning signal line drive circuit 104 and the video signal line driving circuit 180 via the connecting wiring 114. The plurality of scanning signal lines 105 supply scanning signals corresponding to each of the plurality of pixels 115. The plurality of video signal lines 110 supply video signals corresponding to the video displayed on the plurality of pixels 115. In addition, the driver IC 106 supplies a voltage to the anode electrode line 181 and a cathode electrode line 182 electrically connected to the plurality of pixels 115.

### [2-2. Configuration of Subpixel 109 of Display Device 100]

A configuration of the subpixel 109 of the display device 100 will be described with reference to FIG. 15. As shown in FIG. 15, the subpixel 109 includes elements such as a driving transistor 133A, a selection transistor 133C, a capacitance element 134, and a light-emitting element DO. A first terminal of the selection transistor 133C is connected to the video signal line 110, and a gate electrode of the selection transistor 133C is connected to the scanning signal line 105. A first terminal of the driving transistor 133A is connected to the anode electrode line 181, and a second terminal of the driving transistor 133A is connected to one end of the light-emitting element DO. The other end of the light-emitting element DO is connected to the cathode electrode line 182. A gate electrode of the driving transistor 133A is connected to a second terminal of the selection transistor 133C. The capacitance element 134 is connected to the gate electrode of the driving transistor 133A and a capacitance line 130. A gradation signal determining the light-emission intensity of the light-emitting element DO is supplied to the video signal line 110. A signal for selecting a pixel row to which the above gradation signal is written is supplied to the scanning signal line 105. For example, a constant voltage, such as a ground voltage or 0 V, is supplied to the capacitance line 130.

Generally, the voltage supplied to the first terminal of the driving transistor corresponding to the driving transistor 133A in the present invention is higher than the voltage supplied to the second terminal. For example, the current flowing through the semiconductor layer forming the driving transistor is larger than the current flowing through the semiconductor layer forming the selection transistor corresponding to the selection transistor 133C in the present invention.

When current flows through the semiconductor layer forming the driving transistor, the semiconductor layer of the driving transistor of a display device to which the semiconductor devices 10 and 10A are not applied shows significant AC stress degradation at the end portion of the first terminal.

On the other hand, the semiconductor devices 10 and 10A are applied to the driving transistor 133A and the selection transistor 133C. The semiconductor devices 10 and 10A include the AlN layer 120 including the c-axis oriented AlN film and the crystalline polysilicon (111) formed on the AlN layer 120. As a result, the semiconductor devices 10 and 10A have high crystallinity and excellent thermal conductivity. Therefore, variations in the transient characteristics of the driving transistor 133A and the selection transistor 133C to which the semiconductor devices 10 and 10A are applied are suppressed. In addition, the deterioration of transistor characteristics (e.g., AC stress degradation) due to heat generation in the driving transistor 133A and the selection transistor 133C to which the semiconductor devices 10 and 10A are applied is suppressed.

[2-3. Cross-sectional Structure along Line B1-B2 of Display Device 100]

The cross-sectional structure along the line B1-B2 of the display device 100 will be described with reference to FIG. 16. As shown in FIG. 16, the semiconductor layer 122 is provided on the first surface 101A of the substrate 101 via the under layer 121 and the AlN layer 120 including the c-axis oriented AlN film. The semiconductor layer 122 includes the channel region 123, the source region 124A, and the drain region 124B. The semiconductor layer 122 contains the crystalline polysilicon (111). A thickness T2 of the AlN layer 120 overlapping a second region 112 is thicker than a thickness T1 of the AlN layer 120 overlapping a third region 113. For example, based on Table 3 and FIG. 13, the thickness T1 may be 10 nm or more and 100 nm or less, and the thickness T2 may be greater than 100 nm and 120 nm or less.

The gate insulating layer 125, the conductive layer 126, the insulating layer 128, a conductive layer 129, the insulating layer 131, and the conductive layer 132 are provided in this order on the semiconductor layer 122. The conductive layer 126 includes the gate electrode 127 and the scanning signal line 105 (see FIG. 14). The conductive layer 129 includes the capacitance line 130 (see FIG. 15). The conductive layer 132 includes the source electrode 132A, the drain electrode 132B, the anode electrode line 181 (see FIG. 15), the cathode electrode line 182 (see FIG. 15), the connecting wiring 114 (see FIG. 14), and the video signal line 110 (see FIG. 14).

The display device 100 includes a plurality of transistors. For example, each of the plurality of transistors is formed using the semiconductor layer 122 (the channel region 123, the source region 124A, and the drain region 124B), the gate insulating layer 125, and the gate electrode 127. For example, the plurality of transistors includes the driving transistor 133A, the selection transistor 133C, and a plurality of transistors 133B. The driving transistor 133A and the selection transistor 133C are included in the subpixel 109R, the subpixel 109G, and the subpixel 109B, and are transistors for driving the subpixel 109R, the subpixel 109G, and the subpixel 109B. The plurality of transistors 133B is included in the scanning signal line drive circuit 104 and the video signal line driving circuit 180, and are transistors for driving the scanning signal line drive circuit 104 and the video signal line driving circuit 180. In addition, the selection transistor 133C and the video signal line driving circuit 180 are omitted in FIG. 16.

Further, the display device 100 may include the capacitance element. For example, the capacitance element 134 is formed using the gate insulating layer 125 as a dielectric, and the capacitance line 130 and the semiconductor layer 122. In addition, the capacitance element 134 may be formed using the insulating layer 128 as a dielectric, and the capacitance line 130 and the conductive layer 126, or may be formed using the insulating layer 131 as a dielectric, and the capacitance line 130 and the conductive layer 132. Further, the capacitance element 134 may also be formed using the capacitance line 130 and the layers above the capacitance line 130.

An opening 135 reaching the semiconductor layer 122 is provided in the gate insulating layer 125, the insulating layer 128, and the insulating layer 131. The conductive layer 132 is electrically connected to the semiconductor layer 122, the source region 124A, and the drain region 124B through the opening 135. In addition, an opening (not shown) reaching the gate electrode 127 is also provided in the insulating layer 128 and the insulating layer 131, and an opening (not shown) reaching the capacitance line 130 is also provided in the insulating layer 128 and the insulating layer 131.

An insulating layer 136 is provided to cover the conductive layer 132. An insulating layer 137 may be formed on the insulating layer 136. In addition, a conductive layer (not shown) may be formed between the insulating layer 137 and the insulating layer 136, and the capacitance element may be formed using the insulating layer 137 as a dielectric, and a pixel electrode 140 (a conductive layer 139) and the conductive layer. The display device 100 is shown an example in which the insulating layer 137 is formed.

A plurality of openings 138 is provided in the insulating layer 136 and the insulating layer 137. The conductive layer 139 is provided on the insulating layer 137 and in the opening 138. The conductive layer 139 includes the pixel electrode 140. For example, the opening 138 electrically connects the pixel electrode 140 and the conductive layer 132 (the source electrode 132A). Although not shown, for example, the opening 138 electrically connects the conductive layer 139 and a wiring 132C. Further, although not shown, for example, the opening 138 exposes a part of the terminal 107A. The exposed part of the terminal 107A is connected to the flexible printed circuit board 108 using a conductive film such as an anisotropic conductive film (not shown).

An insulating layer 141 is provided to cover an end portion of the pixel electrode 140. The insulating layer 141 includes a partition wall 141A. The partition wall 141A in the display device 100 covers the end portion of the pixel electrode 140, thereby preventing disconnection of a functional layer 148 and a common electrode 149, which are provided on the upper layer of the partition wall 141A.

As shown in FIG. 16 in the second embodiment, the under layer 121, the semiconductor layer 122, the gate insulating layer 125, the conductive layer 126, the insulating layer 128, the conductive layer 129, the insulating layer 131, the conductive layer 132, the insulating layer 136, and the insulating layer 137 are collectively referred to as an array section 170.

Next, the layers above the insulating layer 141 and the partition wall 141A will be described. The functional layer 148 is provided to cover the pixel electrode 140, the partition wall 141A, and the insulating layer 141 included in the display region 102. The common electrode 149 is provided on the upper layer of the functional layer 148 to cover the functional layer 148. A region where the pixel electrode 140 and functional layer 148 contact becomes a light-emitting region in each of the subpixel 109R, the subpixel 109G, and the subpixel 109B. The common electrode 149 is electrically connected to the cathode electrode line 182, and the ground voltage, 0 V, etc., may be supplied.

A configuration of the functional layer 148 can be selected as appropriate. For example, the functional layer 148 can be configured by combining a carrier injection layer, a carrier transport layer, a light-emitting layer, a carrier blocking layer, an exciton blocking layer, and the like. In FIG. 16, an example is shown in which the functional layer 148 has a first layer 144, a second layer 145, and a third layer 146. For example, the first layer 144 is a carrier (hole) injection and transport layer, the second layer 145 is a light-emitting layer, and the third layer 146 is a carrier (electron) injection and transport layer. The second layer 145 (light-emitting layer) can be configured to contain different materials for each of the subpixel 109R, the subpixel 109G, and the subpixel 109B. The light-emitting layer 145R is formed in the subpixel 109R, the light-emitting layer 145G is formed in the subpixel 109G, and the light-emitting layer 145B is formed in the subpixel 109B, in the display device 100.

A light-emitting element 150 in the display device 100 is formed on the insulating layer 137. The light-emitting element 150 is composed of the pixel electrode 140, the functional layer 148, and the common electrode 149. For example, when the driving transistor 133A of the subpixel 109G is driven, a desired current is supplied to the light-emitting element 150, and the light-emitting element 150 emits light.

A sealing film 160 is provided on the light-emitting element 150. The sealing film 160 can be made of a first inorganic insulating layer 152, an organic insulating layer 154, and a second inorganic insulating layer 156. The first inorganic insulating layer 152 and the second inorganic insulating layer 156 are formed to cover at least the display region 102. A cover film 158 is arranged on the second inorganic insulating layer 156.

The first layer 144, the second layer 145 (light-emitting layer), and the third layer 146 included in the functional layer 148, and the common electrode 149 are not arranged on the second region 112, the scanning signal line drive circuit 104, and the video signal line driving circuit 180. The first inorganic insulating layer 152, the organic insulating layer 154, the second inorganic insulating layer 156, and the cover film 158 are arranged on the scanning signal line drive circuit 104 and the video signal line driving circuit 180.

An example in which each of the subpixel 109R, the subpixel 109G, and the subpixel 109B includes one driving transistor 133A is shown in the display device 100. Each of the subpixel 109R, the subpixel 109G, and the subpixel 109B may include semiconductor elements such as a plurality of transistors and capacitance elements.

For example, in the display device 100, the terminal 107A (see FIG. 14), the pixel 115, the scanning signal line drive circuit 104, the video signal line driving circuit 180, and the like are electrically connected using a wiring 126A, a wiring 129A, or the wiring 132C formed in the conductive layer 126, the conductive layer 129, or the conductive layer 132. That is, each element, such as a transistor and a capacitance element, is electrically connected using the wirings formed in the conductive layer 126, the conductive layer 129, or the conductive layer 132.

For example, the materials used to form the insulating layer 137, the first inorganic insulating layer 152, and the second inorganic insulating layer 156 can be general insulating materials, similar to the material that forms the under layer 121.

For example, the materials used to form the insulating layer 136, the insulating layer 141, an insulating layer 142, and the organic insulating layer 154 can be organic compound materials, which have excellent surface flatness, similar to the material that forms the insulating layer 131. The insulating layer 136, the insulating layer 141, the insulating layer 142, and the organic insulating layer 154 cover the unevenness caused by transistors and other semiconductor elements, similar to the insulating layer 131, and the surface of the insulating layer 131 becomes flat.

The sealing film 160 suppresses impurities (moisture, oxygen, etc.) from entering the light-emitting element 150, the transistor, and the like from the outside.

### [2-4. Cross-sectional Structure Along Line C1-C2 of Display Device 100]

The cross-sectional structure along the line C1-C2 of the display device 100 will be described with reference to FIG. 14 and FIG. 17. The cross-sectional structure along the line C1-C2 of the display device 100 is different from the cross-sectional structure along the line B1-B2 of the display device 100, and is the cross-sectional structure near the third side 193 of the display device 100. Differences from the cross-sectional structure along the line B1-B2 of the display device 100 will be described, and similarities to the cross-sectional structure along the line B1-B2 of the display device 100 will be described as necessary, in the description of the cross-sectional structure along the line C1-C2 of the display device 100.

The AlN layer 120 provided in the second region 112 is connected to the wiring 132D through an opening 189. Specifically, the wiring 132D is routed between the insulating layer 131 and the insulating layer 136, and is arranged to contact the wall surfaces of the insulating layer 131, the insulating layer 128, and the gate insulating layer 125, and the surface of the AlN layer 120 in the opening 189 that opens the insulating layer 131, the insulating layer 128, and the gate insulating layer 125. In addition, for example, the wiring 132D is connected to the metal member 184 through an opening 190 that opens the insulating layer 137 and the connecting wiring 183, between the opening 189 and the third side 193. As a result, the AlN layer 120 is connected to the metal member 184.

The metal member 184 has the function of a heat dissipation member (e.g., a heat sink). The thermal conductivity of the AlN layer 120 having the thickness T2 provided in the second region 112 is higher than the thermal conductivity of the AlN layer 120 having the thickness T1 provided in the third region 113. As a result, the AlN layer 120 having the thickness T2 provided in the second region 112 is connected to the metal member 184, and the AlN layer 120, which has a higher thermal conductivity, can efficiently dissipate the heat absorbed from the semiconductor device 10A to the outside of the display device 100.

In addition, the configuration described here for dissipating the heat of the AlN layer 120 to the outside of the display device 100 is an example, and the configuration for dissipating the heat of the AlN layer 120 to the outside of the display device 100 is not limited to the configuration described here.

The first inorganic insulating layer 152 and the second inorganic insulating layer 156 are preferably formed to cover at least the display region 102. In addition, the first inorganic insulating layer 152 and the second inorganic insulating layer 156 are preferably in direct contact with each other around the display region 102, as in the region surrounded by a region 188. As a result, the organic insulating layer 154, which is more hydrophilic compared with the first inorganic insulating layer 152 and the second inorganic insulating layer 156, is sealed by the first inorganic insulating layer 152 and the second inorganic insulating layer 156, thereby more effectively preventing impurities from entering the display device 100 from the outside and from diffusing within the display region 102.

### 3. Third Embodiment

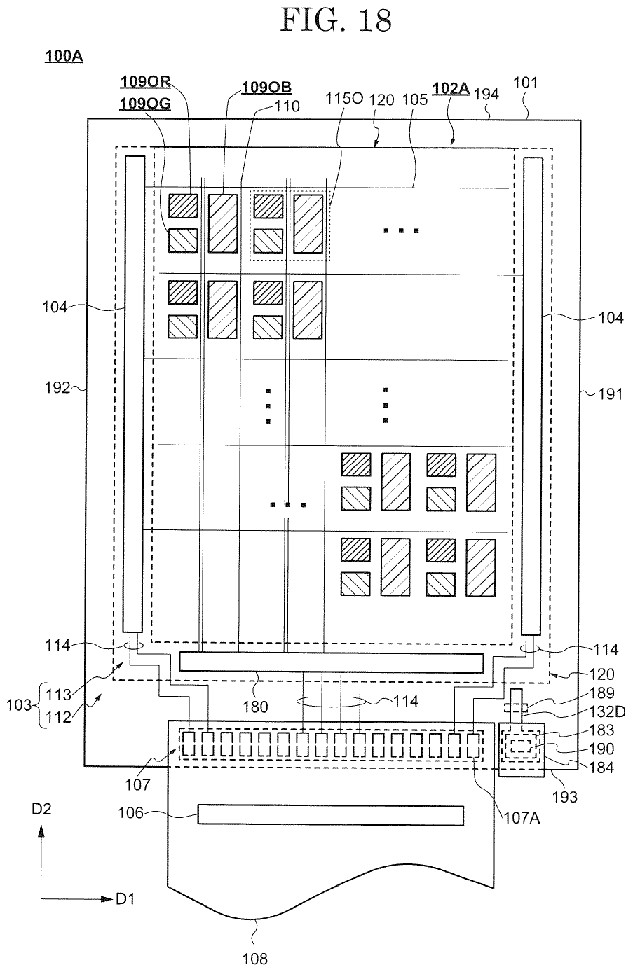

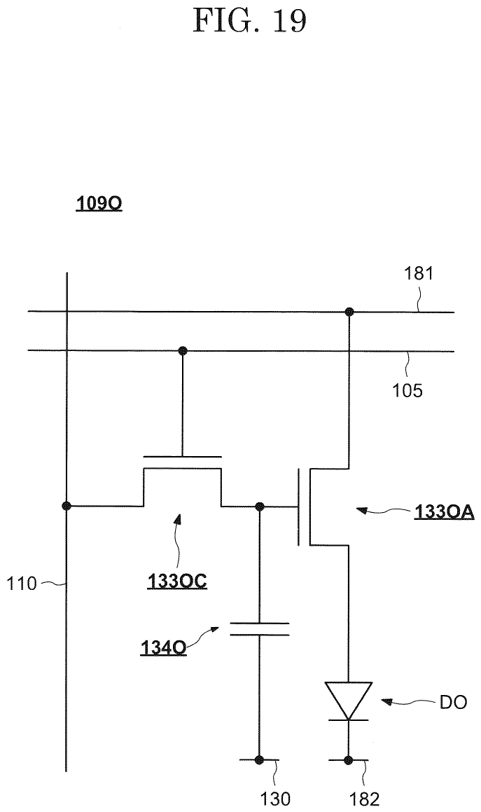

A display device 100A according to a third embodiment will be described with reference to FIG. 18 and FIG. 19. FIG. 18 is a plan view showing a configuration of the display device 100A according to an embodiment of the present invention. FIG. 19 is a circuit diagram showing the circuit configuration of a subpixel 1090 included in a pixel 1150 of the display device 100A. Descriptions of the same or similar configurations as those in FIG. 1A and FIG. 1B to FIG. 17 will be omitted here.

As shown in FIG. 18, the display device 100A includes a display region 102A. The display device 100A is different from the display device 100 according to the second embodiment in that the semiconductor layer of the transistor formed in the display region 102A is different from the semiconductor layer of the transistor formed in the peripheral region 103. Differences from the display device 100 will be described, and similarities to the display device 100 according to the second embodiment will be described as necessary, in the description of the display device 100A.

The display region 102A includes a plurality of pixels 1150 arranged in a matrix in the direction D1 and the direction D2. The pixel 1150 includes a subpixel 109OR, a subpixel 1090G, and a subpixel 1090B. Configurations other than the display region 102A include the same configuration as the display device 100 according to the second embodiment, and a description thereof will be omitted here.

In the case where the subpixels are not distinguished from one another, the subpixel is expressed as the subpixel 1090. In the case where the subpixels are distinguished from one another, the subpixels are expressed as the subpixel 109OR, the subpixel 1090G, and the subpixel 1090B, respectively.

As shown in FIG. 19, the subpixel 1090 includes elements such as a driving transistor 1330A, a selection transistor 1330C, a capacitance element 1340, and the light-emitting element DO. The semiconductor layer forming the driving transistor 1330A, the selection transistor 1330C, and the capacitance element 1340 is different from the driving transistor 133A, the selection transistor 133C, and the capacitance element 134 included in the subpixel 109 in that the semiconductor layer contains an oxide semiconductor. Other aspects of the subpixel 1090 are similar to those of the subpixel 109, and a description thereof will be omitted here.

In addition, the semiconductor layer forming the subpixel 109OR, the subpixel 1090G, and the subpixel 1090B includes the oxide semiconductor, and the configuration other than the semiconductor layer of the subpixel 109OR, the subpixel 1090G, and the subpixel 1090B is the same as the subpixel 109R, the subpixel 109G, and the subpixel 109B. Therefore, descriptions of configurations other than the semiconductor layer of the subpixel 109OR, the subpixel 1090G, and the subpixel 1090B will be omitted.

For example, an oxide semiconductor containing two or more metals including indium (In) is used as the oxide semiconductor contained in the semiconductor layer of the display region 102A. The proportion of indium to the entire semiconductor layer of the display region 102A is 50% or more. For example, in addition to indium, gallium (Ga), zinc (Zn), aluminum (Al), hafnium (Hf), yttrium (Y), zirconia (Zr), and lanthanoids are used as the oxide semiconductor contained in the semiconductor layer of the display region 102A.

In addition, the semiconductor layer of the display region 102A may be amorphous or crystalline. Further, the semiconductor layer of the display region 102A may be a mixed phase of amorphous and crystalline.

The semiconductor layer of the transistor formed in the peripheral region 103 according to the third embodiment contains the crystalline polysilicon (111), similar to the display device 100 according to the second embodiment.

That is, the transistor included in the display region 102A of the display device 100A is made of the oxide semiconductor, and the transistor included in the peripheral region 103 of the display device 100A is made of the crystalline polysilicon (111).

Similar to the display device 100, the display device 100A includes the AlN layer 120 (see FIG. 18) including the c-axis oriented AlN film. Therefore, the AlN layer 120 including the c-axis oriented AlN film can absorb the heat generated by the operation of both transistors made of the oxide semiconductor included in the display region 102A and the crystalline polysilicon (111), and dissipate the absorbed heat from the metal member 184 connected to the AlN layer 120.

### 4. Fourth Embodiment

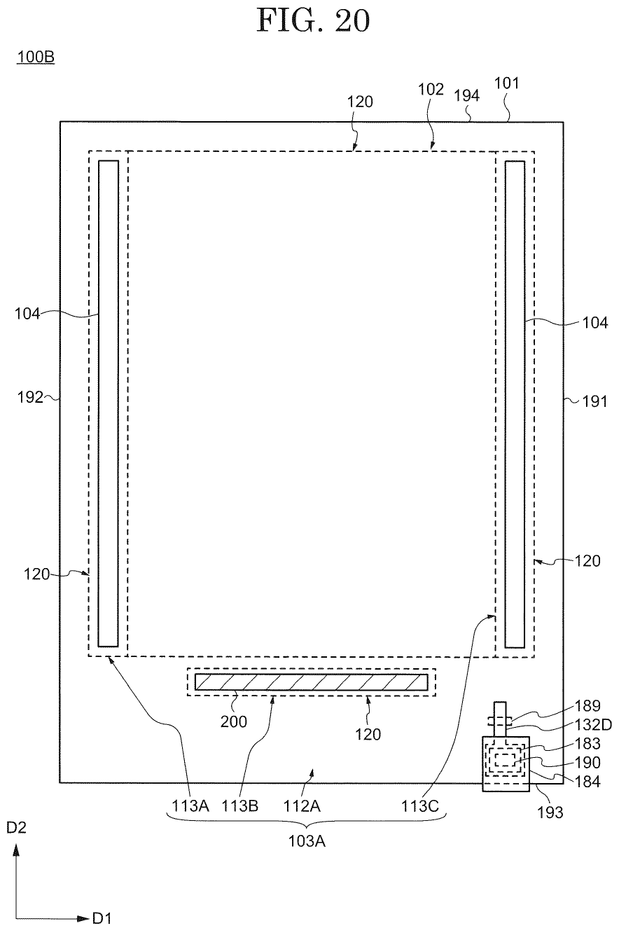

A display device 100B according to a fourth embodiment will be described with reference to FIG. 20. FIG. 20 is a plan view showing a configuration of the display device 100B according to an embodiment of the present invention. In addition, to enhance the visibility of FIG. 20, the plurality of connecting wirings 114, the plurality of video signal lines 110, the plurality of scanning signal lines 105, the plurality of pixels 115, the terminal portion 107, and the flexible printed circuit board 108 included in the display device 100B are omitted. Descriptions of the same or similar configurations as those in FIG. 1A and FIG. 1B to FIG. 19 will be omitted here.

The display device 100B includes the video signal line driving circuit 180 and a driver IC 200 (see FIG. 20) having similar functions as the driver IC 106. For example, the driver IC 200 is arranged on the substrate 101 using a COG (Chip on Glass) method. The display device 100B is different from the display device 100 according to the second embodiment in that it does not include the video signal line driving circuit 180 and the driver IC 106, and includes the driver IC 200. In addition, the display device 100B includes the driver IC 200, so that a configuration of a peripheral region 103A is different from that of the peripheral region 103 according to the second embodiment. Differences from the display device 100 will be described in the description of the display device 100B, and similarities to the display device 100 according to the second embodiment in the description of the display device 100B will be described as necessary.

As shown in FIG. 20, the peripheral region 103A includes a second region 112A, a third region 113A, a third region 113B, and a third region 113C. Similar to the second region 112, the second region 112A is a region that includes an AlN layer thicker than the AlN layer 120 in the display region 102 (first region). Similar to the third region 113, the third region 113A, the third region 113B, and the third region 113C are regions that include the AlN layer 120 that is the same thickness as the AlN layer 120 in the display region 102 (first region).

The third region 113A and the third region 113C include the scanning signal line drive circuit 104. The third region 113B includes the driver IC 200.

The AlN layer 120 having the thickness T2 provided in the second region 112A is connected to the metal member 184 via the opening 189, the wiring 132D, the opening 190, and the connecting wiring 183. Similar to the display device 100 according to the second embodiment, the metal member 184 has the function of a heat dissipation member (e.g., a heat sink). The AlN layer 120 having the thickness T2 provided in the second region 112 is connected to the metal member 184, and the AlN layer 120, which has a higher thermal conductivity, can dissipate the heat absorbed from the semiconductor device 10A included in the scanning signal line drive circuit 104, the semiconductor device 10A included in the display region 102, and the driver IC 200 to the outside of the display device 100B.

Each of the embodiments or some of the embodiments described above as an embodiment of the present invention can be appropriately combined and implemented as Iong as no contradiction is caused.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A method for manufacturing a semiconductor device comprising:
forming a c-axis oriented aluminum nitride layer on a glass substrate, the c-axis being oriented substantially perpendicular to a surface of the glass substrate;
forming an amorphous silicon layer on the c-axis oriented aluminum nitride layer;
annealing the amorphous silicon layer to form crystalline polysilicon containing crystal grains whose (111) planes are oriented parallel to the surface of the c-axis oriented aluminum nitride layer; and
forming a plurality of transistors including the crystalline polysilicon.

2. The method for manufacturing a semiconductor device according to claim 1, further comprising
nitriding the side of the c-axis oriented aluminum nitride layer on which the amorphous silicon layer is formed.

3. The method for manufacturing a semiconductor device according to claim 2, wherein
the nitriding includes annealing the surface of the c-axis oriented aluminum nitride layer using a nitrogen-containing gas or treating the c-axis oriented aluminum nitride layer with a nitrogen-containing plasma.

4. The method for manufacturing a semiconductor device according to claim 1, further comprising
oxidizing the side of the c-axis oriented aluminum nitride layer on which the amorphous silicon layer is formed.

5. The method for manufacturing a semiconductor device according to claim 4, wherein
the oxidizing includes annealing the surface of the c-axis oriented aluminum nitride layer using an oxygen containing gas, or treating the c-axis oriented aluminum nitride layer with an oxygen-containing plasma.

6. The method for manufacturing a semiconductor device according to claim 1, wherein
the c-axis oriented aluminum nitride layer is formed using a sputtering method.

7. The method for manufacturing a semiconductor device according to claim 6, wherein
the thickness of the c-axis oriented aluminum nitride layer is 10 nm or more and 100 nm or less.

8. The method for manufacturing a semiconductor device according to claim 1, wherein
the amorphous silicon layer is formed using a plasma CVD method or a sputtering method.

9. The method for manufacturing a semiconductor device according to claim 1, wherein
the crystalline polysilicon is formed using laser annealing.

10. The method for manufacturing a semiconductor device according to claim 9, wherein
the laser annealing is performed by excimer laser annealing or solid-state laser annealing.

11. The method for manufacturing a semiconductor device according to claim 1, further comprising:
forming wiring on the crystalline polysilicon; and
forming an opening for connecting the c-axis oriented aluminum nitride layer to the wiring.

12. A method for manufacturing a display device including the method for manufacturing a semiconductor device according to claim 10 comprising
forming, on the glass substrate on which the transistors are formed, a first region including a plurality of pixels; a third region surrounding the first region and including a drive circuit for controlling the plurality of pixels; and a second region surrounding the third region,
wherein the second region is formed to overlap the opening.

13. The method for manufacturing a display device according to claim 12, wherein
the thickness of the c-axis oriented aluminum nitride layer overlapping the first region and the third region is 10 nm or more and 100 nm or less, and
the thickness of the c-axis oriented aluminum nitride layer overlapping the second region is thicker than the thickness of the c-axis oriented aluminum nitride layer in the first region and the third region.

14. The method for manufacturing a display device according to claim 12 further comprising:
forming an oxide semiconductor on the c-axis oriented aluminum nitride layer; and
forming a plurality of transistors including the oxide semiconductor, wherein
the plurality of pixels is formed using a plurality of transistors including the oxide semiconductor, and
the drive circuit is formed using a plurality of transistors including the crystalline polysilicon.

15. The method for manufacturing a display device according to claim 12 wherein
the plurality of pixels and a portion of the drive circuit are formed using a plurality of transistors including the crystalline polysilicon, and
another portion of the drive circuit is a driver IC.

16. A semiconductor device comprising:
a glass substrate including a first surface;
a c-axis oriented aluminum nitride layer arranged on the first surface, the c-axis being oriented substantially perpendicular to the first surface;
crystalline polysilicon arranged on the aluminum nitride layer and including crystal grains whose (111) planes are oriented parallel to the surface of the c-axis oriented aluminum nitride layer;
a first insulating layer arranged on the crystalline polysilicon;
a first electrode arranged on the first insulating layer;
a second insulating layer arranged on the first electrode; and
a second electrode and a third electrode arranged on the second insulating layer and electrically connected to the crystalline polysilicon.

17. The semiconductor device according to claim 16 wherein
the thickness of the c-axis oriented aluminum nitride layer is 10 nm or more and 100 nm or less.

18. The semiconductor device according to claim 16 further comprising a nitride layer arranged between the c-axis oriented aluminum nitride layer and the crystalline polysilicon,
wherein
the nitride layer has a higher nitrogen concentration than the c-axis oriented aluminum nitride layer.

19. The semiconductor device according to claim 16 further comprising an oxide layer arranged between the c-axis-oriented aluminum nitride layer and the crystalline polysilicon,
wherein
the oxide layer has a higher oxygen concentration than the c-axis-oriented aluminum nitride layer.
